(19) United States
(12) Patent Application Publication
(10) Pub. No.: US 2008/0029903 A1
(43) Pub. Date: Feb. 7, 2008

(54) Chip-stacked package structure

(75) Inventor: Hung Tsun Lin, Hsinchu (TW)

Correspondence Address: REED SMITH LLP, Suite 1400, 3110 Fairview Park Drive, Falls Church, VA, 22042, US

(73) Assignees: Chipmos Technologies Inc.; Chipmos Technologies (Bermuda) Ltd.

(21) Appl. No.: 11/826,302

(22) Filed: Jul. 13, 2007

(30) Foreign Application Priority Data
Aug. 7, 2006 (TW) 095128828

(51) Int. Cl. H01L 23/48; H01L 21/60

(52) U.S. Cl. 257/777; 438/109; 257/E21.506; 257/E23.01

(57) ABSTRACT

The present invention provides a chip-stacked structure, comprising: a substrate with a plurality of terminals and a chip-stacked structure formed by a plurality of stacked chips and fixedly connected to the substrate. Wherein an active surface of each chip in the chip-stacked structure is provided with a plurality of pads and the back surface of each chip is provided with an insulation layer. The plurality of chips is connected by an adhesive layer provided between the active surface of one chip and the insulation layer on the back surface of another chip and thus the chip-stacked structure is formed. The plurality of pads is electrically connected to the plurality of terminals on the substrate with a plurality of metal wires.

### BACKGROUND OF THE INVENTION

1. Field of the Invention

The present invention relates to a chip-stacked package structure, and more particularly, to a chip-stacked package structure in which the bending degree of metal wires is decreased by reversed wire-bonding process and insulation layer and a ball spacer is provided in the adhesive layer of the chip-stacked structure.

2. Description of the Prior Art

In semiconductor post-processing, many efforts have been made for increasing scale of the integrated circuits such as memories while minimizing the occupied area. Accordingly, the development of three-dimensional (3D) packaging technology is in progress and the idea of making up a chip-stacked structure has been disclosed.

The prior art has taught that a chip-stacked structure can be formed by firstly stacking a plurality of chips and then electrically connecting the chips to the substrate in a wire bonding process. FIG. 1 is a cross-sectional view of a prior chip-stacked package structure for chips of same or similar sizes. As shown in FIG. 1, the prior chip-stacked package structure 100 comprises a package substrate 110, chip 120a, chip 120b, a spacer 130, a plurality of wires 140, and an encapsulant 150. The package substrate 110 is provided with a plurality of pads 112. The chips 120a and 120b are respectively provided with peripherally arranged pads 122a and 122b. The chip 120a is provided on the package substrate 110 while the chip 120b is provided on the chip 120a with a spacer 130 intervened there-between. The chip 120a is electrically connected to the package substrate 110 by bonding two ends of one of the wires 140 to the pads 112 and 122a respectively. The chip 120b is electrically connected to the package substrate 110 in similar manner. The encapsulant 150 is then provided on the package substrate 110 to cover the chips 120a and 120b and the wires 140.

Since the pads 122a and 122b are respectively provided at the peripheral of the chip 120a and the chip 120b, there is a need to apply the spacer 130 to prevent the chip 120b from directly contacting with the chip 120a for performing the subsequent wire-bonding. However, the use of spacer 130 increases the thickness of the prior chip-stacked package structure 100.

Moreover, in another conventional package structure of as shown in FIG. 2, a spacer 130 with a certain thickness is applied to keep the two chips at a proper distance for performing the subsequent wire-bonding. In addition, a stud bump 141 is formed on the end of pad 13 of the chip to decrease the bending degree of metal wires 140. It is obvious that the thickness of stacked package structure cannot be decreased by the stacking and packaging method with spacer 130 applied and the number of stacked chips is also limited.

Another common defect of stacked package structures in FIGS. 1 and 2 is that the position where the spacer 130 is provided cannot fully support upper chips (120b; 20). Thus, if the thickness of the chip is too thin, the wafer would be broken during the wire bonding process. Therefore, the thickness of chips in the stacked package structure with the spacer 130 need a constant thickness, so as to the chip-stacked package structure can not be stacked by a lot of chips. In addition, in the process of chip stacking, the short circuit would be occurred due to the upper chips (120b; 20) contacted to the lower wire 140s. The molding process is performed in the stacked package structure with the spacer 130 after the wire bonding process is completed. A void would be generated in the gap between the upper and the lower chips which is as thick as that of a spacer 130 or a spacing layer 150. The encapsulant would be cracked when the void expands under a high temperature.

### SUMMARY OF THE INVENTION

In view of the drawbacks and problems of the prior chip-stacked package structure as mentioned above, the present invention provides a three-dimensional chip-stacked structure for packaging multi-chips with similar size.

It is an object of the present invention to provide a chip-stacked structure in which an insulation layer is formed on the back surface of each chip so that the chips can be stacked on the metal wires, so as to the scale of the integrated circuits can be increased while the thickness in a package is reduced.

It is another object of the present invention to provide a chip-stacked structure to prevent the wafers from breaking during the wire bonding process.

It is still another object of the present invention to provide a chip-stacked structure to prevent the void is generated in the gap between stacked chips after the molding process is performed.

It is a further object of the present invention to provide a ball-shaped insulator in a chip-stacked structure to keep the distance between the stacked chips.

According to abovementioned objects, the present invention provides a chip-stacked structure, comprising: a substrate with a plurality of terminals and a chip-stacked structure formed by a plurality of stacked chips and fixedly connected to the substrate. Wherein an active surface of each chip in the chip-stacked structure is provided with a plurality of pads and the back surface of each chip is provided with an insulation layer. The plurality of chips is connected by an adhesive layer that provided between the active surface of one chip and the insulation layer on the back surface of another chip and thus the chip-stacked structure is formed. The plurality of pads is electrically connected to the plurality of terminals on the substrate with a plurality of metal wires.

The present invention also provides a chip-stacked structure, comprising: a substrate with a plurality of terminals and a chip-stacked structure formed by a plurality of stacked chips and fixedly connected to the substrate. Wherein an active surface of each chip in the chip-stacked structure is provided with a plurality of pads and the back surface of each chip is provided with an insulation layer. The active surface of the plurality of chips is connected with the insulation layer on the back surface of another chip via the ball spacer to form a chip-stacked structure. The plurality of pads located on the plurality of chips that are electrically connected to the plurality of terminals on the substrate by a plurality of metal wires.

The present invention then provides a chip-stacked structure, comprising a lead-frame and a chip-stacked structure. The lead-frame comprises a plurality of inner leads arranged in rows facing each other and a die pad with an upper surface and a lower surface provided between the plurlaity of inner leads. The chip-stacked structure is composed of a plurality of chips stacked together and is fixedly connected to the upper surface of the lead-frame. Wherein an active surface of each chip in the chip-stacked structure is provided with a plurality of pads and the back surface of each chip is provided with an insulation layer. The plurality of chips is connected by an adhesive layer with a plurality of ball spacers in it provided between the active surface of one chip and the insulation layer on the back surface of another chip and thus the chip-stacked structure is formed. The plurality of pads is electrically connected to the plurality of inner leads of the lead-frame through a plurality of metal wires.

The present invention further provides a chip-stacked structure, comprising a lead-frame and a plurality of chip-stacked structures. The lead-frame comprises a plurality of inner leads arranged in rows facing each other and a die pad provided between the plurality of inner leads. The die pad has an upper surface and a lower surface opposite the upper surface. Each of the plurality of chip-stacked structures is composed of a plurality of chips stacked together. The plurality of chip-stacked structure are fixedly connected to the upper surface and lower surface of the lead-frame respectively. Wherein an active surface of each chip in the chip-stacked structure is provided with a plurality of pads and the back surface of each chip is provided with an insulation layer. The plurality of chips is connected by an adhesive layer with a plurality of ball spacers in it provided between the active surface of one chip and the insulation layer on the back surface of another chip and thus the chip-stacked structure is formed. The plurality of pads is electrically connected to the plurality of inner leads of the lead-frame through a plurality of metal wires.

The present invention then provides a method for stacking the chip-stacked structure, the steps which comprising: providing a substrate with a plurality of terminals thereon; providing a first chip, a plurality of pads being provided on the active surface of the first chip and an insulation layer being provided on the back surface and connected to the substrate; then providing a heating device to perform a baking process for solidifying the insulation layer on the back surface of the first chip; providing a plurality of wires with a reversed wire bonding process for electrically connecting the plurality of pads on the first chip and the plurality of terminals on the substrate; then forming a first adhesive layer on the active surface of the first chip; providing a second chip with an insulation layer on the back surface and said insulation layer being connected to the first adhesive layer; then providing another heating device for solidifying the first adhesive layer; then providing a plurality of wires for electrically connecting the plurality of pads on the second chip and the plurality of terminals on the substrate. Then, the steps of the above-mentioned are repeated to form the chip-stacked structure of the present invention.

The present invention then provides another method for stacking a chip-stacked structure, the steps which comprising: providing a lead-frame comprising a plurality of inner leads arranged in rows facing each other and a die pad provided between the plurality of inner leads; then providing a first chip, a plurality of pads being provided on an active surface of said first chip and an insulation layer being provided on the back surface and the insulation layer being fixedly connected to the substrate; then providing a heating device to perform a baking process for solidifying the insulation layer on the back surface of the first chip; providing a plurality of wires with a reversed wire bonding process for electrically connecting the plurality of pads on the first chip and the plurality of terminals on the substrate; then forming a first adhesive layer on the active surface of the first chip and selectively applying a plurality of ball spacers in first adhesive layer; providing a second chip with a plurality of pads on active surface and an insulation layer on the back surface and said insulation layer being connected to the first adhesive layer; then providing a heating device for solidifying the first adhesive layer; then providing a plurality of metal wires with a reversed wire bonding process for electrically connecting the plurality of pads on the second chip and the plurality of inner leads of the lead-frame. Then, the steps of the above-mentioned are repeated for forming the chip-stacked structure of the present invention.

The present invention then provides another method for stacking a chip-stacked structure, the steps which comprising: providing a lead-frame comprising a plurality of inner leads arranged in rows facing each other and a die pad with an upper surface and a lower surface provided between the plurality of inner leads; then providing a first chip, a plurality of pads being provided on the active surface of said first chip and an insulation layer being provided on the back surface of the chip and said insulation layer being fixedly connected to the upper surface of the die pad; then providing a heating device to perform a baking process for solidifying the insulation layer on the back surface of the first chip; providing a plurality of wires with a reversed wire bonding process for electrically connecting the plurality of pads on the first chip and the plurality of inner leads of the leadframe; then forming a first adhesive layer on the active surface of the first chip; providing a second chip with an insulation layer provided on its back surface and connected to the first adhesive layer; then providing a heating device for solidifying the first adhesive layer; then providing a plurality of wires with reversed wire bonding process for electrically connecting the plurality of pads on the second chip and the plurality of inner leads of the lead-frame; meantime, reversing the leadframe for 180 degrees; then providing a third chip, a plurality of pads being provided on an active surface of the third chip and an insulation layer being provided on the back surface of the third chip and fixedly connected to the lower surface of the die pad; meantime, providing another heating device for solidifying the insulation layer; then providing a plurality of metal wires with a reversed wire bonding process for electrically connecting the plurality of pads on the third chip and the plurality of inner leads of the lead-frame; then forming a second adhesive layer on the active surface of the third chip; providing a fourth chip with an insulation layer that is provided on the back surface and connected to the second adhesive layer; providing another heating device for solidifying the second adhesive layer; then providing a plurality of wires with reversed wire bonding process for electrically connecting the plurality of pads on the fourth chip and the plurality of inner leads of the lead-frame. Then, the steps of the above-mentioned are repeated to form the chip-stacked structure of the present invention.

### BRIEF DESCRIPTION OF THE DRAWINGS

FIG. 1 is a diagram schematically showing a conventional chip-stacked package structure.

FIG. 2 is a diagram schematically showing a conventional chip-stacked package structure.

FIGS. 3A˜B are a plain view and a cross-sectional view of the chip of the present invention.

FIG. 4 is a cross-sectional view of the stacked structure of the present invention.

FIG. 5 is a cross-sectional view of the stacked structure of the present invention with ball spacers.

FIG. 6 is a cross-sectional view of the stacked structure of the present invention with lead-frame as a substrate.

FIG. 7 is a cross-sectional view of the stacked structure of the present invention with lead-frame as a substrate.

FIG. 8 is a cross-sectional view of the stacked structure of the present invention with lead-frame as a substrate.

FIG. 9 is a cross-sectional view of the stacked structure of the present invention with lead-frame as a substrate.

FIG. 10 is a cross-sectional view of the stacked structure of the present invention with lead-frame as a substrate.

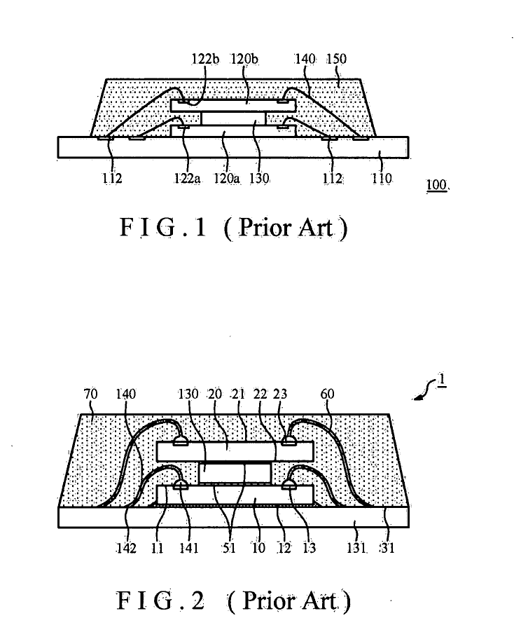

### DESCRIPTION OF THE PREFERRED EMBODIMENT

The present invention will now be described more fully hereinafter with reference to the accompanying drawings, in which preferred embodiments are shown. In the following, the well-known knowledge regarding the chip-stacked structure of the invention such as the formation of chip and the process of thinning the chip would not be described in detail to prevent from arising unnecessary interpretations. However, this invention will be embodied in many different forms and should not be construed as limited to the embodiments set forth herein.

According to the semiconductor packaging process, a Front-End-Process experienced wafer is performed a thinning process to reduce the thickness to a value between 2 mil and 20 mil, and then the polished wafer is applied with a polymer material such as a resin or a B-Stage resin by coating or printing. Next, a post-exposure baking or lighting process is applied to the polymer material so that the polymer material becomes a viscous semi-solidified gel-like material. Subsequently, a removable tape is attached to the viscous semi-solidified gel-like material and then the wafer is sawed into chips or dies. At last, these chips or dies are stacked on and connected to a substrate to form a chip-stacked structure.

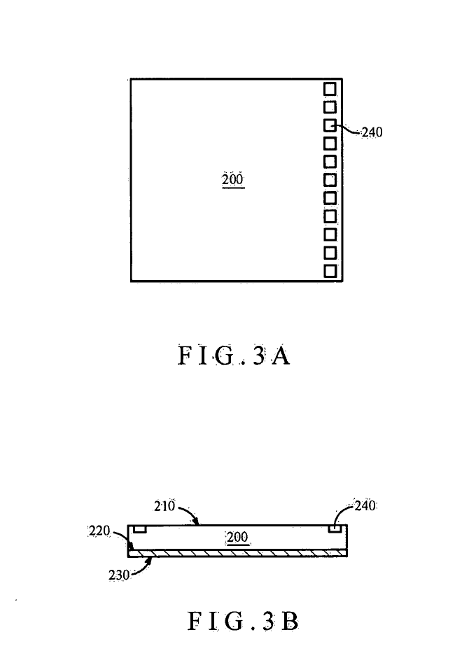

Referring to FIGS. 3A and 3B, shows a plane view and a cross-sectional view of a chip 200 that has experienced the above-mentioned processes. As shown in FIG. 3B, the chip 200 has an active surface 210 and a back surface 220 in opposition to the active surface 210 with an insulation layer 230 formed on the back surface 220. It is to be noted that the resin material of the insulation layer 230 in the present invention is not limited to the above-mentioned. The object of the insulation layer 230 is to insulate and can be formed with any adhesive insulating material, such as die attached film, for connecting the chip and the substrate together. In addition, a plurality of pads 240 is provided on the active surface 210 of the chip 200. The plurality of pads 240 can be provided on the periphery of the chip 200.

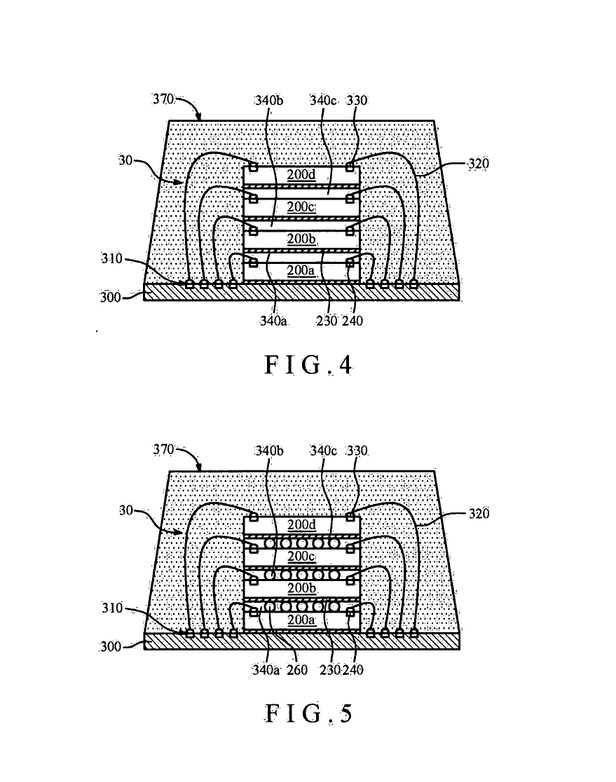

Then, referring to FIG. 4, which is a cross-sectional view of a stacked package structure of the present invention. As shown in FIG. 4, in the present embodiment, a substrate 300 with a plurality of terminals 310 thereon. Wherein the substrate 300 can be a PCB or a lead-frame; when the substrate 300 is a PCB, it can become the carrier substrate of BGA. Then, a chip 200a is adhered to the substrate 300 through the insulation layer 230 on the back surface of the chip 200a and the terminal 310 is exposed. Then a heating or baking process is performed for solidifying the insulation layer 230 on the back surface 220 of the chip and the substrate 300. The wire bonding process is then performed to bond the pads 240 on chip 200a and terminals 310 on the substrate 300 through a plurality of metal wires 320. It is to be noted that a reversed wire bonding is performed in the present invention to bond the chip 200a to the substrate 300. Before performing the reversed wire bonding process, a stud bump 330 is formed on the pads 240 of chip 200a. After the metal wires 320 and the terminals 310 on the substrate are connected, the ends of metal wires 320 are then connected with the stud bump 330. The object of forming this stud bump in advance is to prevent the bending degree of the metal wires 320 at the pads 240 of chip 200a from becoming too large. Thus not only the problem of wire sweep can be avoided in the following process, but the thickness of the package structure can also be effectively reduced.

In the following, an adhesive layer 340a is applied to the active surface 210 of chip 200a by a coating or printing process and thus the whole active surface 210, the ends of metal wires 320, and the stud bump 330 are all covered. This adhesive layer 340a can be a polymer material, and more particularly, a B-Stage resin. The thickness of the adhesive layer 340a is larger than the degree of the largest bending degree of metal wires 320, and therefore the thickness of adhesive layer 340a is between 2 mil and 10 mil. Then the baking process can be selectively processed for solidifying the adhesive layer 340a.

Then, another chip 200b is adhered to the adhesive layer 340a so that the insulation layer 230 on the back surface of chip 200b is attached to the adhesive layer 340a. The surface of adhesive layer 340a that has experienced coating or printing process may not be smooth but can sill be close fitted to the insulation layer 230 since the insulation layer 230 on the back surface of the chip can be a semi-solidified B-Stage resin. Then the heating or baking process is performed for fixedly connecting the chip 200b and the adhesive layer 340a. And then another reversed wire bonding process is performed to bond the pads 240 on the chip 200b with the terminals 310 on the substrate 300 through a plurality of metal wires 320. Similarly, a stud bump 330 is also formed on the pads 240 of chip 200b before the reversed wire bonding process in the present embodiment. After the metal wires 320 and the terminals 310 on the substrate are connected, the ends of metal wires 320 are then connected with the stud bump 330. The above-mentioned steps are then repeated. An adhesive layer 340b is applied on the active surface 210 of chip 200b and the active surface 210 is fully covered. A baking process is selectively performed, and another chip 200c is adhered to the adhesive layer 340b. A chip-stacked structure 30 can thus be completed by repeating the above-mentioned baking and wire bonding processes. Finally, a molding process is performed and an encapsulant 370 covers the chip-stacked structure 30, the plurality of metal wires 320, and the terminals 310 on the substrate, as shown in FIG. 4.

In the present embodiment, the ends of metal wires 320 are located on the pads 240 of the chip since the reversed wire bonding process is applied. It is obvious that the bending degree of metal wires 320 at the ends is smaller than the bending degree of the bonding ends of metal wires 320 at the terminals 310. Thus the height of chips 200a, 200b, 200c, and 200d can be decreased in the process of chip stacking. Since an insulation layer 230 is provided on the back surface 220 of chip 200, the short circuit can also be avoided when chips are stacked on the ends of metal wires 320 and the stud bump 330. Meantime, the stud bump 330 would be formed on each pad on the chip before the reversed wire bonding process is performed. Although some of the pads 240 can not be connected to the substrate 300, yet in the present embodiment, the stud bump 330 would still be formed on these pads as dummy pad that acts as spacer between stacked chips (chips 200a and 200b for example). Moreover, since metal wires 320 located between two chips (chips 200a and 200b for example) that are covered by the adhesive layer 340, not only can the contact between metal wires 320 be avoided, but the strength of metal wires 320 can also be enhanced and the problem of wire sweep in the molding process can thus be avoided more easily. Furthermore, since the adhesive layer 340 fully covers the active surface 210 of the chip, thus there will be no gap between two chips (chips 200a and 200b for example). Therefore, there is no void would not be occurred between the chips after the molding process is completed and the problem of chip cracking can also be solved. Moreover, since the adhesive layer 340 fully covers the active surface 210 of chip, the chip would not be suspended in the air and the problem of broken wafer can also be solved. Accordingly, the improvement disclosed by the present invention can reduce the thickness of package structure for chips and increase the density of staking.

Moreover, as shown in FIG. 5, the present invention further provides another embodiment for consolidating and keeping the distance between the two chips (chips 200a and 200b for example). In the present embodiment, a ball spacer 360 is mixed in the adhesive layer 340 in FIG. 4. This ball spacer 360 is made of an elastic polymer material, such as resin. In the above-mentioned chip stacking process, a plurality of ball spacers 360 are mixed evenly with the adhesive layer 340 and can be formed on the active surface 210 of each chip by coating or printing. The ball spacers 360 can become supports between the chips (chips 200a and 200b for example) with its volume. To support effectively, the height of ball spacers 360 can be between 35 um and 200 um. The chip stacking process of the present embodiment is the same as that in FIG. 4, so the process would not be given unnecessary details herein.

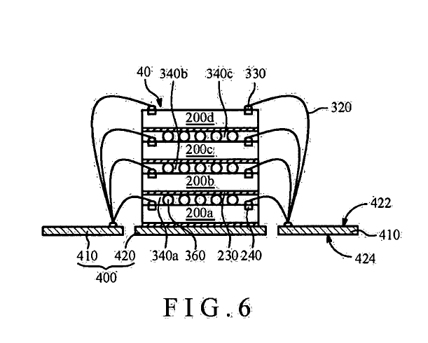

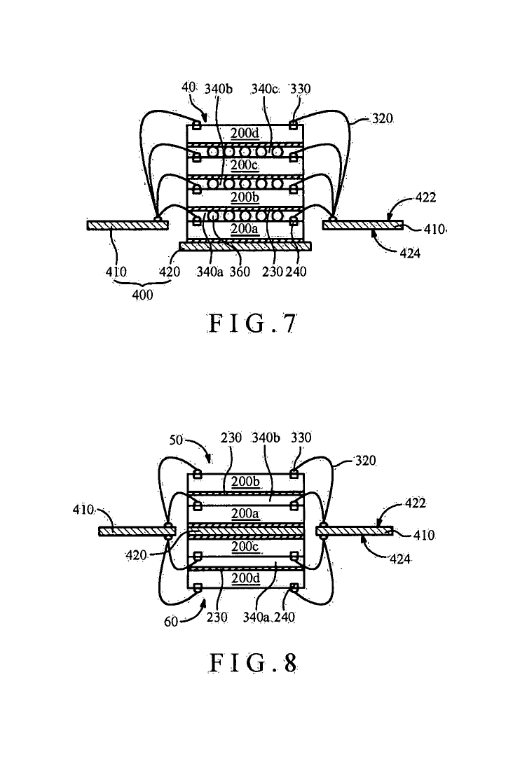

The present invention further provides another embodiment, as shown in FIGS. 6 and 7. In the present embodiment, the substrate in FIGS. 4 and 5 is substituted by a lead-frame. When the substrate is a lead-frame 400, the lead-frame 400 has at least a plurality of inner leads 410 arranged in rows facing each other and a die pad 420 provided between the plurality of inner leads 410. It is obvious that in the embodiment in FIG. 6, the die pad 420 and the inner leads 410 are coplanar. Meantime, the die pad 420 has an upper surface 422 and a lower surface 424.

Then, another chip 200a is adhered to the upper surface 422 of die pad 420 through the insulation layer 230 on the back surface of the chip 200a. Then, a heating process or baking process is performed for solidifying the insulation layer 230 between the back surface 220 of the chip and the die pad 420. The reversed wire bonding process is then performed to bond the pads 240 on the chip 200a and the inner leads 410 through a plurality of metal wires 320. Before performing the reversed wire bonding process, a stud bump 330 is formed on the pads 240 of chip 200a. After the plurality of metal wires 320 and the inner leads 410 of lead-frame 400 are connected, the ends of metal wires 320 are then connected with the stud bump 330. In the following, an adhesive layer 340a mixed with a plurality of ball spacers 360 is applied to the active surface 210 of chip 200a by a coating or printing process and thus the whole active surface 210, the ends of metal wires 320, and the stud bump 330 are all covered. The adhesive layer 340a can be a polymer material, and more particularly, a B-Stage resin; this ball spacer 360 is made up of an elastic polymer material. In the present embodiment, the thickness of the adhesive layer 340a is larger than the degree of the largest bending degree of metal wires 320, and the thickness of adhesive layer 340a is between 2 mil and 10 mil. Meantime, when the distance between two chips (chips 200a and 200b for example) need to keep, the height of ball spacers 360 can be selected between 35 um and 200 um. And then the baking process can be selectively to perform for solidifying the adhesive layer 340a.

Then, another chip 200b is adhered to the adhesive layer 340a so that the insulation layer 230 on the back surface of the chip 200b is attached to the adhesive layer 340a. The surface of adhesive layer 340a that has experienced coating or printing process may not be a smooth surface due to the insulation layer 230 is a semi-solidified B-Stage resin that located on the back surface of the chip, so that the insulation layer 230 can be adhered tightly to the abrasive surface of the adhesive layer 340a. Then, the baking process is performed for fixedly connecting the chip 200b to the adhesive layer 340a. Next, another reversed wire bonding process is performed to bond the pads 240 on the chip 200b with the inner leads 410 through a plurality of metal wires 320. Similarly, before performing the reversed wire bonding process, a stud bump 330 is formed on the pads 240 of chip 200a. After the metal wires 320 and the inner leads 410 of lead-frame 400 are connected, the ends of metal wires 320 are then connected with the stud bump 330. The above-mentioned steps are then repeated. An adhesive layer 340b mixed with a plurality of ball spacers 360 is applied on the active surface 210 of chip 200b and fully covers the active surface 210. Another chip 200c is then adhered to the adhesive layer 340b after performing a baking process. A chip-stacked package structure 40 can be completed by repeating the above-mentioned baking and reversed wire bonding processes. Finally, a molding process is performed and an encapsulant (not shown in the drawing) is covered over the chip-stacked structure 40, the plurality of metal wires 320, and the inner leads 410, as shown in FIG. 6.

Moreover, referring again to FIG. 7 shows an embodiment in which a lead-frame is used as substrate. The different between FIG. 6 and FIG. 7 is that the heights of die pad 420 of on the lead-frame 400. The rest of the structure in FIG. 7 is the same as that in FIG. 6, so thus, the related process of chip stacking for chip stacking would not be given unnecessary details. In the embodiment in of FIG. 7, the die pad 420 and inner leads 410 of lead-frame 400 are vertically at different height. More particularly, the die pad 420 is formed as a down-set structure. It is to be noted that in the embodiment in FIGS. 6 and 7, the plurality of ball spacers 360 can be alternatively to add into the adhesive layer 340. Therefore, the package structure without the ball spacers 360 therein also can be another embodiment of the present invention.

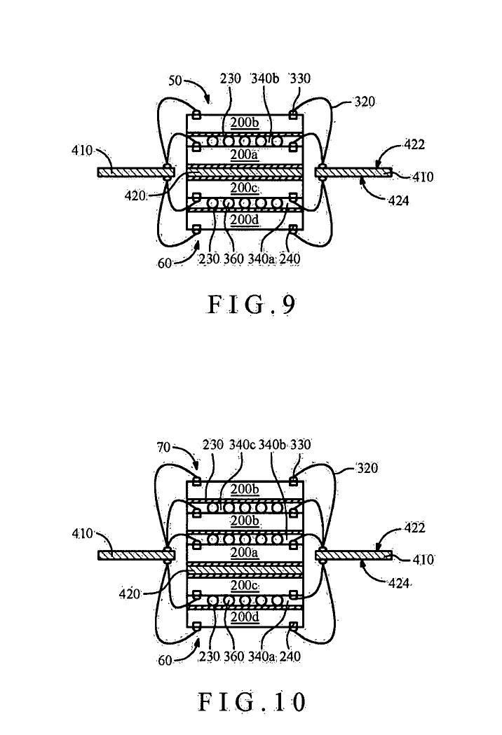

The present invention further provides a stacked package structure with lead-frame as the substrate, as shown in FIGS. 8 and 9. First, referring to FIG. 8, when the substrate is a lead-frame 400, the lead-frame 400 is provided with a plurality of inner leads 410 arranged in rows facing each other and a die pad 420 is located between the plurality of inner leads 410. It is to be noted that in the present embodiment, the die pad 420 and inner leads 410 are coplanar. The die pad 420 has an upper surface 422 and a lower surface 424. Then another chip 200a is adhered to the upper surface 422 of the die pad 420 through the insulation layer 230 on the back surface of the chip 200a. Then, a heating or baking process is performed for solidifying the insulation layer 230 between the back surface 220 of the chip and the die pad 420. The reversed wire bonding process is then performed to bond the pads 240 on chip 200a and inner leads 410 through a plurality of metal wires 320. Before performing the reversed wire bonding process, a stud bump 330 is formed on the pads 240 of chip 200a. After the metal wires 320 and the inner leads 410 of lead-frame 400 are connected, the ends of metal wires 320 are connected with the stud bump 330. Following, an adhesive layer 340a is applied to the active surface 210 of chip 200a by a coating or printing process and thus the whole active surface 210, the ends of metal wires 320, and the stud bump 330 are all covered. This adhesive layer 340a can be a polymer material, and more particularly, a B-Stage resin. The thickness of the adhesive layer 340a is larger than the degree of the largest bending degree of metal wires 320, and thus the thickness of adhesive layer 340a is between 2 mil and 10 mil. Then, the baking process can be alternatively performed for solidifying the adhesive layer 340a.

Then, another chip 200b is adhered to the adhesive layer 340a so that the insulation layer 230 on the back surface of chip 200b can be attached to the adhesive layer 340a. The surface of the adhesive layer 340a has experienced coating or printing process that may not be a smooth surface due to the insulation layer 230 is a semi-solidified B-Stage resin that located on the back surface of the chip, so that the insulation layer 230 can be adhered tightly to the abrasive surface of the adhesive layer 340a. Then, the baking process is performed for fixedly connecting the chip 200b and the adhesive layer 340a. Next, another reversed wire bonding process is performed to bond the pads 240 on the chip 200b with the inner leads 410 through a plurality of metal wires 320. Similarly, before performing the reversed wire bonding process, a stud bump 330 is formed on the pads 240 of chip 200a. After the metal wires 320 and the inner leads 410 of lead-frame 400 are connected, the ends of metal wires 320 are then connected with the stud bump 330. A plurality of chip-stacked structures 50 can be formed on the upper surface 422 of die pad 420 by repeating the above-mentioned steps.

Then, the leadframe is reversed for 180 degrees so that the lower surface 424 of die pad 420 of leadframe 400 is faced upward. Then, performing above-mentioned steps in the present embodiment. The chip 200c and the lower surface 424 of the die pad 420 are fixedly connected. After the baking process is performed, the reversed wire bonding process is performed to bond the chip 200c and the inner leads 410 through metal wires 320. An adhesive layer 340b is then applied on the active surface 210 of chip 200c. The chip 200c and the adhesive layer 340b are fixedly connected. After the baking process is performed, the chip 200d and the inner leads 410 are connected through metal wires 320. Similarly, the above-mentioned steps can be repeated to form another plurality of chip-stacked structure 60 on the lower surface 424 of the die pad 420. Finally, a molding process is performed, and an encapsulant (not shown in the drawing) is covered over the chip-stacked structure 50, chip-stacked structure 60, the plurality of metal wires 320, and inner leads 410, as shown in FIG. 8. Moreover, in the embodiment of FIG. 9, the adhesive layer 340 is mixed with a plurality of ball spacers 360 and the rest part of the structure is the same as the embodiment in FIG. 8, and thus related processes would not be given unnecessary details.

It is obvious that when the inner leads 410 of lead-frame 400 and the die pad 420 are vertically at different height, the chip-stacked structure 40 can be an unsymmetrical stack structure as shown in FIG. 10, with one side being odd numbers of stacked chips (chip-stacked structure 70 for example) and the other side being even numbers of stacked chips (chip-stacked structure 60 for example), which is not limited in the present invention. Meantime, in the embodiment of the present invention, the stacking process for chip 200 can be performed according to the height difference (especially when the downset structure is formed) between the die pad 420 and the inner leads 410. Therefore, a plurality of chip-stacked structures (chip-stacked structure 70 for example) can be formed on the upper surface 422 of the die pad 420 and only one chip is connected to the lower surface 424 of die pad 420. This chip-stacked structure is also an embodiment of the present invention. The chip stacking process in the present embodiment is the same as in FIGS. 8 and 9. A plurality of ball spacers 360 can also be selectively mixed in the adhesive layer 340, therefore, the related processes would not be given unnecessay details.

According to the above-mentioned process, the present invention provides a method for stacking and packaging chips, the steps of which are as follows. First, a substrate with a plurality of terminals is provided. Then a first chip is provided with a plurality of pads on the active surface and an insulation layer on the back surface which is in opposition to the active surface. The insulation layer is located on the chip that is connected to the substrate. In the present invention, the substrate can be a PCB and can further become a carrier substrate of BGA. A heating device is then provided for performing a baking process to solidify the insulation layer on the back surface of the first chip. Then, the reversed wire bonding process is performed to provide a plurality of metal wires for electrically connecting the plurality of pads on the first chip and the plurality of terminals on the substrate. Wherein a stud bump is first formed on the pads of chip through a reversed wire bonding process. After the metal wires and the terminals of substrate are connected, the ends of metal wires are then connected to the stud bump. The distance between stacked chips can be decreased since the degree of bending degree of the ends of metal wires is smaller. Then, a first adhesive layer is formed on the active surface of first chip. A second chip is provided. An active surface of the second chip is provided with a plurality of pads and a back surface of the second chip in opposition to the active surface is provided with an insulation layer which is connected to the first adhesive layer. A heating device is then provided for solidifying the first adhesive layer. A plurality of metal wires are provided for electrically connecting the plurality of pads on the second chip and the plurality of terminals on the substrate. A second adhesive layer is formed on the active surface of the second chip. A third chip is then provided. An active surface of the third chip is provided with a plurality of pads and a back surface of the third chip in opposition to the active surface is provided with an insulation layer which is connected to the second adhesive layer. Similarly, a heating device is provided for solidifying the second adhesive layer. Then, the reversed wire bonding process is performed to provide a plurality of metal wires for electrically connecting the plurality of pads on the third chip and the plurality of terminals on the substrate. The chip-stacked structure of the present invention can thus be formed by repeating the above-mentioned steps.

Moreover, in the above-mentioned for packaging multi-chip-stacking, the step of mixing a plurality of ball spacers in the adhesive layer that can be added. Meantime, after the adhesive layer is formed on the active surface of a plurality of chips, a heating device can be alternatively applied to perform a baking process for solidifying the adhesive layers.

The present invention then provides another method for stacking and packaging chips, the steps of which are as follows. First, a leadframe is provided, the leadframe being composed of a plurality of inner leads arranged in rows facing each other and a die pad provided between the plurality of inner leads. Then, a first chip is provided. The active surface of first chip is provided with a plurality of pads and the back surface in opposition to the active surface that is provided with an insulation layer. The insulation layer is located on the back surface of the chip that is fixedly connected to the die pad. In the present embodiment, the die pad and the inner leads can be located coplanar and a structure with different height can be formed. A heating device is then provided for performing a baking process to solidify an insulation layer on the back surface of the first chip. The reversed wire bonding process is then performed to provide a plurality of metal wires for electrically connecting the plurality of pads on the first chip and the plurality of inner leads on the leadframe. Before performing the reversed wire bonding process, a stud bump is formed on the pads of chip. Then, the metal wires and the inner leads of lead-frame are connected, and the ends of metal wires are connected with the stud bump. The distance between stacked chips can be decreased since the bending degree of the metal wires at ends is smaller. In the following, a first adhesive layer is formed on the active surface of the first chip. Meantime, a plurality of ball spacers can be selectively mixed in the first adhesive layer. Then, the second chip is provided. The active surface of the second chip is provided with a plurality of pads and a back surface of the second chip in opposition to the active surface that is provided with an insulation layer which is connected to the first adhesive layer. A heating device is then provided for solidifying the first adhesive layer. The wire bonding process is performed to provide a plurality of metal wires for electrically connecting the plurality of pads on the second chip and the plurality of inner leads on the leadframe. A second adhesive layer is then formed on the active surface of the second chip. A plurality of ball spacers can be selectively mixed in the second adhesive layer. A third chip is then provided. An active surface of the third chip is provided with a plurality of pads and a back surface of the third chip in opposition to the active surface is provided with an insulation layer which is connected to the second adhesive layer. Similarly, a heating device is provided for solidifying the second adhesive layer. Then, the reversed wire bonding process is performed to provide a plurality of metal wires for electrically connecting the plurality of pads on the third chip and the plurality of inner leads on the leadframe. The chip-stacked structure of the present invention can be formed by repeating the above-mentioned steps.

It is to be noted that in the above-mentioned multi-chip-stacking and packaging method, the die pad and inner leads can be coplanar and can be vertically in different height, especially when the die pad is formed as a down-set structure. Both kinds of lead-frame are the embodiments of the present invention. Moreover, a plurality of ball spacers can also be mixed in the adhesive layer in the present embodiment. After the adhesive layer is formed on the active surface of a plurality of chips, a heating device can also be applied selectively for performing a baking device to solidifying these adhesive layers.

The present invention further provides another method for stacking and packaging chips. First, a lead-frame is provided, the leadframe being composed of a plurality of inner leads arranged in rows facing each other and a die pad provided between the plurality of inner leads. The die pad is provided with an upper surface and a lower surface. Then, a first chip is provided. The active surface of first chip is provided with a plurality of pads and the back surface in opposition to the active surface is provided with an insulation layer. The insulation layer is formed on the back surface of the chip that is fixedly connected to the upper surface of the die pad. In the present embodiment, the die pad and the inner leads can be coplanar and can also be a structure with different height. A heating device is then provided for performing a baking process to solidify an insulation layer on the back surface of the first chip. The reversed wire bonding process is then performed to provide a plurality of metal wires for electrically connecting to the plurality of pads on the first chip and the plurality of inner leads on the lead-frame. Before performing the reversed wire bonding process, a stud bump is formed on the pads of chip. Then, the metal wires and the inner leads of lead-frame are connected, and the ends of metal wires are connected with the stud bump. The distance between the stacked chips can be decreased since the bending degree of the metal wires at ends is smaller. In the following, a first adhesive layer is formed on the active surface of the first chip. Then, the second chip is provided. The active surface of the second chip is provided with a plurality of pads and a back surface of the second chip in opposition to the active surface that is provided with an insulation layer and is connected to the first adhesive layer. A heating device is then provided for solidifying the first adhesive layer. The wire bonding process is performed to provide a plurality of metal wires for electrically connecting to the plurality of pads on the second chip and the plurality of inner leads on the lead-frame. At this time, the lead-frame is reversed for 180 degrees. Then, the third chip is provided. An active surface of the third chip is provided with a plurality of pads and a back surface of the third chip in opposition to the active surface is provided with an insulation layer which is fixedly connected to the lower surface of the die pad. Similarly, a heating device is then provided for solidifying the insulation layer. The reversed wire bonding process is then performed to provide a plurality of metal wires for electrically connecting the plurality of pads on the third chip and the plurality of inner leads on the leadframe. A second adhesive layer is then formed on the active surface of the third chip. Then, the fourth chip is provided. An active surface of the fourth chip is provided with a plurality of pads and a back surface of the fourth chip in opposition to the active surface is provided with an insulation layer which is connected to the second adhesive layer. A heating device is then provided for solidifying the second adhesive layer. The reversed wire bonding process is then performed to provide a plurality of metal wires for electrically connecting the plurality of pads on the fourth chip and the plurality of inner leads on the leadframe. The chip-stacked structure of the present invention can thus be formed by repeating the above-mentioned steps. It is obvious that when the inner leads of lead-frame and the die pad are vertically at different height, the chip-stacked structure can become an unsymmetrical stack, with one side being odd numbers of stacked chips and the other side being even numbers of stacked chips, which is not limited in the present invention. Moreover, in each embodiment, the stacking of chips can be processed according to the height difference (especially when the downset structure is formed) between die pad and inner leads. Therefore, a plurality of chip-stacked structures can also be formed on the upper surface of die pad and only one chip is connected to the lower surface of die pad. This kind of stacked structure is also an embodiment of the present invention and is not limited in the present invention.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A chip-stacked package structure, comprising a substrate provided with a plurality of terminals and a chip-stacked structure stacked by a plurality of chips, said chip-stacked structure being fixedly connected to said substrate, and a plurality of metal wires electrically connecting said chip-stacked structure and said plurality of terminals on said substrate, the improvement of said chip-stacked package structure being:
an active surface of each chip in said chip-stacked structure being provided with a plurality of pads and a back surface in opposition to said active surface of each chip being provided with an insulation layer, an adhesive layer being provided between said plurality of chips for connecting said active surface of each chip and said insulation layer on said back surface of another chip to form said chip-stacked structure, and a plurality of metal wires being provided for electrically connecting said plurality of pads on said plurality of chips and said plurality of terminals on said substrate.

2. The chip-stacked package structure as set forth in claim 1, wherein said adhesive layer is a polymer material or a B-Stage material.

3. The chip-stacked package structure as set forth in claim 1, wherein said adhesive layer is a die attached film or a B-Stage material.

4. The chip-stacked package structure as set forth in claim 1, wherein said substrate is a PCB or a lead-frame.

5. A chip-stacked package structure, comprising a substrate provided with a plurality of terminals and a chip-stacked structure stacked by a plurality of chips, said chip-stacked structure being fixedly connected to said substrate, and a plurality of metal wires electrically connecting said chip-stacked structure and said plurality of terminals on said substrate, the improvement of said chip-stacked package structure being:
an active surface of each chip in said chip-stacked structure being provided with a plurality of pads and a back surface in opposition to said active surface of each chip being provided with an insulation layer, an adhesive layer mixed with a plurality of ball spacers being provided between said plurality of chips for connecting said active surface of each chip and said insulation layer on said back surface of another chip to form said chip-stacked structure, and a plurality of metal wires being provided for electrically connecting said plurality of pads on said plurality of chips and said plurality of terminals on said substrate.

6. The chip-stacked package structure as set forth in claim 5, wherein said ball spacers are a polymer material.

7. The chip-stacked package structure as set forth in claim 5, wherein the height of said ball spacers is 35˜200 um.

8. A chip-stacked package structure, comprising a lead-frame, a die pad, and a chip-stacked structure, said lead-frame comprising a plurality of inner leads arranged in rows facing each other and a die pad provided between said plurality of inner leads, said die pad having an upper surface and a lower surface in opposition to said upper surface, said chip-stacked structure being stacked by a plurality of chips and fixedly connected to said upper surface of said die pad, a plurality of metal wires electrically connecting said chip-stacked structure and said plurality of inner leads arranged in rows facing each other, the improvement of said chip-stacked package structure being:
an active surface of each chip in said chip-stacked structure being provided with a plurality of pads and a back surface in opposition to said active surface of each chip being provided with an insulation layer, an adhesive layer mixed with a plurality of ball spacers being provided between said plurality of chips for connecting said active surface of each chip and said insulation layer on said back surface of another chip to form said chip-stacked structure, and a plurality of metal wires being provided for electrically connecting said plurality of pads on said plurality of chips and said plurality of inner leads on said lead-frame arranged in rows facing each other.

9. The chip-stacked package structure as set forth in claim 8, wherein said ball spacers are a polymer material.

10. The chip-stacked package structure as set forth in claim 8, wherein the height of said ball spacers is 35˜200 um.

11. A chip-stacked package structure, comprising a leadframe, a die pad, and a plurality of chip-stacked structures, said leadframe comprising a plurality of inner leads arranged in rows facing each other and a die pad provided between said plurality of inner leads, said die pad having an upper surface and a lower surface in opposition to said upper surface, said plurality of chip-stacked structures being stacked by a plurality of chips and be respectively fixedly connected to said upper surface and said lower surface of said die pad, a plurality of metal wires electrically connecting said plurality of chip-stacked structures and said plurality of inner leads arranged in rows facing each other, the improvement of said chip-stacked package structure being:
an active surface of each of said chips in said plurality of chip-stacked structures being provided with a plurality of pads and a back surface in opposition to said active surface of each of said chips being provided with an insulation layer, an adhesive layer mixed with a plurality of ball spacers being provided between said plurality of chips for connecting said active surface of each chip and said insulation layer on said back surface of another chip to form chip-stacked structure, and a plurality of metal wires being provided for electrically connecting said plurality of pads on said plurality of chips and said plurality of inner leads on said leadframe arranged in rows facing each other.

12. The chip-stacked package structure as set forth in claim 11, wherein said die pad and said plurality of inner leads arranged in rows facing each other are vertically at different heights.

13. The chip-stacked package structure as set forth in claim 13, wherein the number of chips stacked on said upper surface of said die pad and the number of chips stacked on said lower surface of said die pad are different.

14. The chip-stacked package structure as set forth in claim 15, wherein the number of chips stacked on said lower surface can be one.

15. A chip-stacked packaging method, the steps of said packaging method comprising:
a. providing a substrate, said substrate being provided with a plurality of terminals;
b. providing a first chip, an active surface of said first chip being provided with a plurality of pads and a back surface in opposition to said active surface being provided with an insulation layer, said insulation layer being fixedly connected to said substrate;
c. providing a heating device for solidifying said insulation layer;
d. providing a plurality of metal wires, reversed wire bonding process being performed for electrically connecting said plurality of pads on said first chip and said plurality of terminals on said substrate with said plurality of metal wires;
e. forming an adhesive layer on said active surface of said first chip;
f. providing a second chip, an active surface of said second chip being provided with a plurality of pads and a back surface of in opposition to said active surface being provided with an insulation layer, said insulation layer being connected to said first adhesive layer;
g. providing a heating device for solidifying said first adhesive layer;
h. providing a plurality of metal wires, reversed wire bonding process being performed for electrically connecting said plurality of pads on said second chip and said plurality of terminals on said substrate with said plurality of metal wires; and
i. repeating steps d˜h for forming a chip-stacked structure.

16. The chip-stacked packaging method as set forth in claim 15, wherein said adhesive layer is mixed with a plurality of ball spacers.

17. A chip-stacked packaging method, the steps of said packaging method comprising:
a. providing a leadframe comprising a plurality of inner leads arranged in rows facing each other and a die pad provided between said plurality of inner leads;
b. providing a first chip, an active surface of said first chip being provided with a plurality of pads and a back surface in opposition to said active surface being provided with an insulation layer, said insulation layer being fixedly connected to said die pad;
c. providing a heating device for solidifying said insulation layer;
d. providing a plurality of metal wires, reversed wire bonding process being performed for electrically connecting said plurality of pads on said first chip and said plurality of inner leads on said leadframe with said plurality of metal wires;
e. forming an adhesive layer on said active surface of said first chip;
f. providing a second chip, an active surface of said second chip being provided with a plurality of pads and a back surface of in opposition to said active surface being provided with an insulation layer, said insulation layer being connected to said first adhesive layer;
g. providing a heating device for solidifying said first adhesive layer;
h. providing a plurality of metal wires, reversed wire bonding process being performed for electrically connecting said plurality of pads on said second chip and said inner leads on said leadframe with said plurality of metal wires; and
i. repeating steps d-h for forming a chip-stacked structure.

18. The chip-stacked packaging method as set forth in claim 17, wherein said adhesive layer is mixed with a plurality of ball spacers.

19. A chip-stacked packaging method, the steps of said packaging method comprising:
a. providing a leadframe comprising a plurality of inner leads arranged in rows facing each other and a die pad provided between said plurality of inner leads, said die pad having an upper surface and a lower surface;
b. providing a first chip, an active surface of said first chip being provided with a plurality of pads and a back surface in opposition to said active surface being provided with an insulation layer, said insulation layer being fixedly connected to said upper surface of said die pad;
c. providing a heating device for solidifying said insulation layer;
d. providing a plurality of metal wires, reversed wire bonding process being performed for electrically connecting said plurality of pads on said first chip and said plurality of inner leads on said leadframe with said plurality of metal wires;
e. forming a first adhesive layer on said active surface of said first chip;
f. providing a second chip, an active surface of said second chip being provided with a plurality of pads and a back surface of in opposition to said active surface being provided with an insulation layer, said insulation layer being connected to said first adhesive layer;
g. providing a heating device for solidifying said first adhesive layer;
h. providing a plurality of metal wires, reversed wire bonding process being performed for electrically connecting said plurality of pads on said second chip and said inner leads on said leadframe with said plurality of metal wires;
i. reversing said leadframe, and said lower surface of die pad of said leadframe facing downward;
j. providing a third chip, an active surface of said third chip being provided with a plurality of pads and a back surface in opposition to said active surface being provided with an insulation layer, said insulation layer being fixedly connected to said lower surface of said die pad;
k. providing a heating device for solidifying said adhesive layer;
l. providing a plurality of metal wires, said plurality of metal wires electrically connecting said plurality of pads on said third chip and said plurality of inner leads on said leadframe;
m. forming a second adhesive layer on said active surface of said third chip;
n. providing a fourth chip, an active surface of said fourth chip being provided with a plurality of pads and a back surface in opposition to said active surface being provided with an insulation layer, said insulation layer being fixedly connected to said second adhesive layer;
o. providing a heating device for solidifying said second adhesive layer; and
p. providing a plurality of metal wires, said plurality of metal wires electrically connecting said plurality of pads on said fourth chip and said plurality of inner leads on said leadframe.

20. The chip-stacked packaging method as set forth in claim 19, wherein said first adhesive layer and said second adhesive layer are mixed with a plurality of ball spacers.
